(19) United States
(12) Patent Application Publication
(10) Pub. No.: US 2004/0032269 A1
(43) Pub. Date: Feb. 19, 2004

(54) Paving material analyzer system, sensor and method

(75) Inventors: Robert A. Sovik, Clifton Park, NY (US); Richard N. Hosterman, Buskirk, NY (US); George G. Moross, Scotia, NY (US)

Correspondence Address: HOFFMAN WARNICK & D'ALESSANDRO, LLC, 3 E-COMM SQUARE, ALBANY, NY, 12207

(73) Assignee: TransTech Systems, Inc., Schenectady, NY

(21) Appl. No.: 10/218,630

(22) Filed: Aug. 14, 2002

(51) Int. Cl. G01R 27/26

(52) U.S. Cl. 324/663

(57) ABSTRACT

A sensor for a paving material analyzer is disclosed including means for allowing moving, non-dragging contact of an operative component with the paving material. A paving material analyzer system incorporating the sensor is also disclosed. The invention also includes a method for analyzing paving material.

This application is related to U.S. Pat. Nos. 5,900,736 and 6,414,497 and currently pending U.S. Ser. No. 10/185,510, filed Jun. 28, 2002, which is a continuation-in-part application of U.S. Pat. No. 6,414,497.

### BACKGROUND OF THE INVENTION

1. Technical Field

The present invention relates generally to paving material density analyzers. More particularly, the present invention relates to a sensor for a paving material analyzer system and a method for analyzing paving material.

2. Related Art

During paving operations, paving material is usually laid at about 75% of acceptable compaction. Acceptable compaction is a recommended level of compaction that reduces variations in the material, such as air voids, that can create potential defects in the paving material. It is highly advantageous to compact the paving material to a level as close to acceptable compaction as possible. Unfortunately, the level of compaction is not readily apparent by viewing the compacted paving material. In order to address this problem, measurement of dielectric properties of paving material is known to be very useful for determining material density, a key indicator of compaction level.

One pavement density indicator device is that of Blackwell, U.S. Pat. No. 3,784,905. Blackwell's device measures dielectric properties of the asphalt, which is representative of the change in density in the asphalt. The device of Blackwell has many disadvantages. For example, in order to obtain a reading, the Blackwell device must be moved at extremely slow speeds across the material being tested and, accordingly, requires an extended time period to provide a determination. The Blackwell device, due to its excessive weight, also requires a large sled frame (contact area) to be dragged across the pavement surface. In addition, since the sensor is positioned above the paving material, inaccuracies result in the measurement due to the space created.

Other paving material analyzer systems are disclosed in U.S. Pat. Nos. 5,900,736 and 6,414,497, both of which are hereby incorporated by reference. Referring to FIG. 1, in both of these systems, a paving analyzer system 2 is provided with an analyzer unit 4 and a sensor 6 that is positioned above paving material 8. A space 10 between sensor 6 and paving material 8 generates inaccuracies in the measurements of the dielectric characteristics or impedance. Placing sensor 6 of either of these devices in contact with paving material 8 is generally unacceptable for a number of reasons. First, it prevents movement of sensor 6 because the flat sensor readily adheres to paving material 8. Movement of sensor 6 over paving material 8 is advantageous for sensing changes in density. Forcibly dragging sensor 6 over paving material 8 creates unacceptable shaking of the sensor. Second, dragging contact of either of these sensors also allows paving material 8 to readily adhere to sensor 6. Accumulation of paving material 8 must then be cleaned off for further usage of sensor 6 to be accurate.

In view of the foregoing there is a long felt need for a paving material analyzer system sensor capable of moving, non-dragging contact of an operative component with paving material, but without the above-described disadvantages.

### SUMMARY OF THE INVENTION

The invention overcomes the above shortcomings by providing a sensor capable of moving, non-dragging contact of an operative component with the paving material. In one embodiment, the sensor is shaped into a substantially cylindrical shape to allow rolling contact of the sensor with the paving material. This configuration allows for moving, non-dragging contact and substantially reduces accumulation of paving material on the sensor.

In a first aspect of the invention is directed to a paving material analyzer system comprising: a sensor having means for allowing moving, non-dragging contact of an operative component with the paving material; and a paving material analyzer operatively coupled to the sensor.

A second aspect of the invention provides a sensor for a paving material analyzer, the sensor comprising: a shape allowing moving, non-dragging contact of an operative component with the paving material.

A third aspect of the invention provides a method for analyzing paving material comprising the steps of: generating an electrical field from a sensor while maintaining moving, non-dragging contact of an operative component with the paving material; and analyzing the paving material based on the effect of the paving material on the electric field.

In a fourth aspect of the invention is provided a sensor for a paving material analyzer, the sensor comprising: means for allowing moving, non-dragging contact of an operative component with the paving material.

The foregoing and other features and advantages of the invention will be apparent from the following more particular description of preferred embodiments of the invention.

### BRIEF DESCRIPTION OF THE DRAWINGS

The preferred embodiments of this invention will be described in detail, with reference to the following figures, wherein like designations denote like elements, and wherein:

FIG. 1 shows a prior art paving material analyzer system;

FIG. 2 shows a schematic view of a paving material analyzer system according to the invention;

FIG. 3 shows an alternative embodiment for the sensor of FIG. 2; and

FIG. 4 shows a second alternative embodiment for the sensor of FIG. 2.

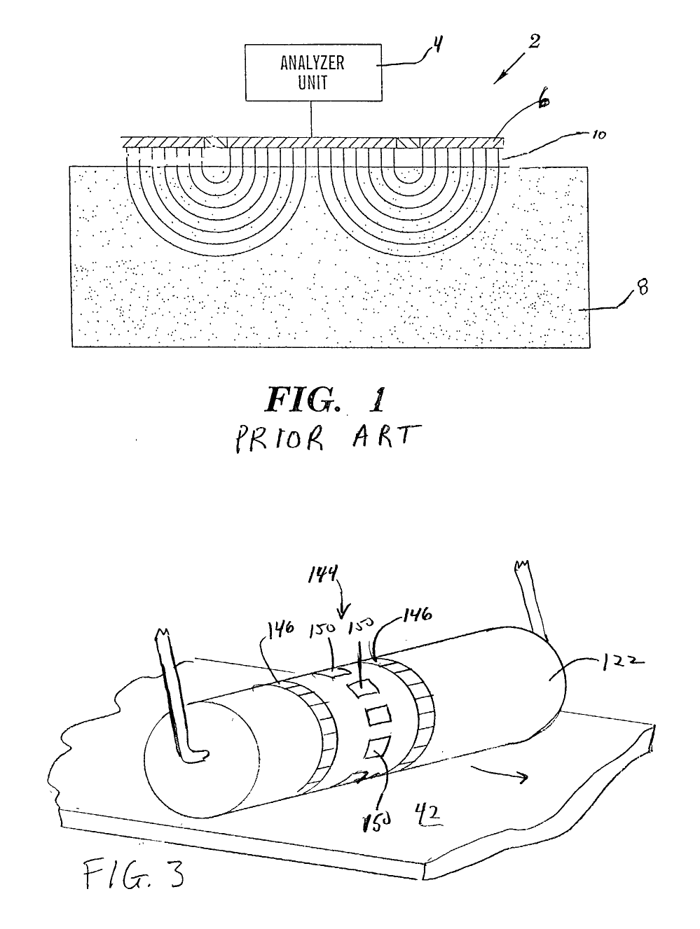

### DESCRIPTION OF THE PREFERRED EMBODIMENTS

While the preferred embodiments will be described in conjunction with the paving environment, other applications of the invention will become apparent to those skilled in the art. The limited description is intended only for ease of explaining the construction and operation of the device. Accordingly, “paving material” should be interpreted broadly to include all varieties of asphalt, cement, concrete, soil, sand, stones, bituminous material and all other forms of in-place material.

Referring to FIG. 2, a schematic view of a paving material analyzer system 20 is shown. System 20 includes a sensor 22 and a pavement material analyzer unit 24. Analyzer unit 24, or any component thereof, may be located adjacent sensor 22 or at a remote location to facilitate its use by a vehicle operator when the system is mounted to a vehicle. Analyzer unit 24 preferably has a sensor circuit 26 and a data analyzer 28. Sensor circuit 26 is an electronic circuit that is operatively coupled to sensor 22 to: 1) apply an electric potential to sensor 22 to generate, or transmit, an electrical field 30 from the sensor proximate paving material 42; and 2) receive at least a part of electrical field 32 back from paving material 42. Data analyzer 28 is operatively coupled to electronic circuit 26 for determining a density of paving material 42 based on the effect of impedance or dielectric characteristics of paving material 42 on the electrical field. The sensor circuit 26 and data analyzer may be any now known of later developed configuration. Details of exemplary configurations are described in U.S. Pat. Nos. 5,900,736 and 6,414,497. Analyzer unit 24 may also include a display 34 and any number of controls 36 for controlling data analyzer 28.

With further reference to FIG. 2, an exemplary structure of sensor 22 is shown. Sensor 22 is constructed to provide moving, non-dragging contact of an operative component 40 with paving material 42. In one embodiment, sensor 22 is shaped, such as in a substantially cylindrical shape, to allow moving, non-dragging contact. In this setting, sensor 22 is mounted via a support 43 (e.g., a handle that is hand held, a mount to a paving machine, etc.) for rolling contact with paving material 42. Electrical communication 45 (e.g., wiring) between analyzer unit 24 and operative component 40 is provided so as to not interfere with movement of sensor 22. As illustrated, electrical interconnections such as wiring are run through support 43 and are coupled to operative component 40 in a known fashion within sensor 22.

Operative component 40 may include a receive section 44 and at least one transmit section 46. In one embodiment, a pair of transmit sections 46 are provided, one positioned on each side of receive section 44. When sensor 22 is provided in a substantially cylindrical shape, each section 44, 46 may extend at least partially around the circumference of the substantially cylindrical shape. If the sections extend only partially about the circumference, receive section 44 would receive an intermittent return signal, which could be analyzed in any of a number of known fashions.

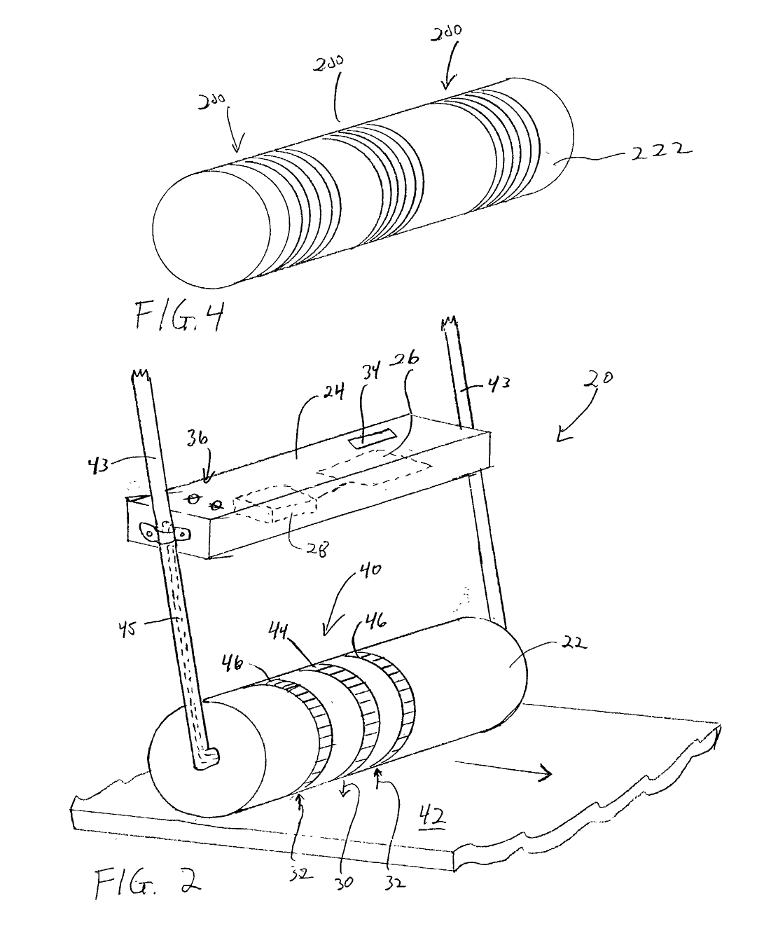

Referring to FIG. 3, an alternative sensor 122 is shown. Sensor 122 includes the same structure as that of FIG. 2 (the analyzer unit has been removed for brevity), except a pair of transmit sections 146 and receive section 150 include a plurality of circumferentially spaced segments. With this setting, receive section 150 would receive an intermittent return signal, which could be analyzed in any of a number of known fashions.

In a second alternative embodiment, shown in FIG. 4, a plurality of transmit and receive section sets 200, i.e., an plurality of operative components, may be spaced along a sensor 222.

The invention also includes a method for analyzing paving material using the above-described system(s). The method includes the steps of: generating an electrical field from a sensor while maintaining moving, non-dragging contact of an operative component with the paving material; and analyzing the paving material based on the effect of the paving material on the electric field. The step of maintaining may include providing sensor 22, 122 with a shape, such as substantially cylindrical, allowing moving, non-dragging contact of the operative component with the paving material. The method of claim 11, wherein the shape.

Although the invention has been described in a manner with one embodiment for providing moving, non-dragging contact of a sensor with paving material, it should be recognized that a number of other structures may be possible and considered within the scope of this invention.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting. Various changes may be made without departing from the spirit and scope of the invention as defined in the following claims.

We claim:

1. A paving material analyzer system comprising:
a sensor having means for allowing moving, non-dragging contact of an operative component with the paving material; and
a paving material analyzer operatively coupled to the sensor.

2. The system of claim 1, wherein the paving material analyzer includes:
an electronic circuit operatively coupled to the sensor to generate an electric field from the sensor proximate the paving material; and
a data analyzer, operatively coupled to the electronic circuit, that determines a density of the paving material based on the effect of impedance characteristics of the paving material on the electrical field.

3. A sensor for a paving material analyzer, the sensor comprising:
a shape allowing moving, non-dragging contact of an operative component with the paving material.

4. The sensor of claim 3, wherein the operative component includes a transmit section and a receive section.

5. The sensor of claim 4, wherein the shape is substantially cylindrical.

6. The sensor of claim 5, wherein the transmit section and the receive section each extend at least partially about a circumference of the substantially cylindrical shape.

7. The sensor of claim 5, wherein the transmit section includes a plurality of circumferentially spaced segments.

8. The sensor of claim 5, further comprising a pair of transmit sections, one positioned to each side of the receive section.

9. The sensor of claim 3, wherein the shape is substantially cylindrical.

10. The sensor of claim 3, further comprising a plurality of operative components spaced along the sensor.

11. A method for analyzing paving material comprising the steps of:
generating an electrical field from a sensor while maintaining moving, non-dragging contact of an operative component with the paving material; and
analyzing the paving material based on the effect of the paving material on the electric field.

12. The method of claim 11, wherein the step of maintaining includes providing the sensor with a shape allowing moving, non-dragging contact of the operative component with the paving material.

13. The method of claim 12, wherein the shape is substantially cylindrical.

14. The method of claim 13, wherein the operative component includes a transmit section and a receive section, each section extending at least partially about a circumference of the substantially cylindrical shape.

15. The method of claim 14, wherein the transmit section includes a plurality of circumferentially spaced segments.

16. The method of claim 14, further comprising a pair of transmit sections, one positioned to each side of the receive section.

17. The method of claim 14, further comprising a plurality of operative components spaced along the sensor.

18. A sensor for a paving material analyzer, the sensor comprising:
means for allowing moving, non-dragging contact of an operative component with the paving material.
